(19) United States
(12) Patent Application Publication
(10) Pub. No.: US 2015/0357336 A1
(43) Pub. Date: Dec. 10, 2015

(54) SEMICONDUCTOR DEVICE AND METHOD OF MANUFACTURING THE SAME

(71) Applicant: Mitsunari SUKEKAWA, Chuo-ku, Tokyo (JP)

(72) Inventor: Mitsunari Sukekawa, Tokyo (JP)

(73) Assignee: PS5 Luxco S.a.r.l., Luxembourg (LU)

(21) Appl. No.: 14/759,901

(22) PCT Filed: Jan. 7, 2014
(86) PCT No.: PCT/JP2014/050064

§ 371 Date: Jul. 8, 2015

(30) Foreign Application Priority Data
Jan. 9, 2013 (JP) 2013-001782

(51) Int. Cl. H01L 27/108

(52) U.S. Cl. CPC H01L 27/10823; H01L 27/10814; H01L 27/10885; H01L 27/10891; H01L 27/10876

(57) ABSTRACT

This semiconductor device is provided with: a silicon pillar that is provided by digging from a main surface of a semiconductor substrate; a first diffusion layer that is provided above the silicon pillar; a second diffusion layer, that is provided from a bottom portion of the silicon pillar to one region of the semiconductor substrate, said one region being continuous to the silicon pillar; a gate electrode in contact with at least a first side surface of the silicon pillar with a gate insulating film therebetween; a first embedding insulating film that surrounds the gate electrode; a second embedding insulating film in contact with a second side surface of the silicon pillar, said second side surface facing the first side surface of the silicon pillar; and a conductive layer, which is electrically connected to the second diffusion layer, and which is in contact with the second embedding insulating film at a position separated from the silicon pillar.

### TECHNICAL FIELD

The present invention relates to a semiconductor device and a method for manufacturing the same, and in particular relates to a semiconductor device containing embedded-gate transistors, and a method for manufacturing the same.

### BACKGROUND

An embedded-gate transistor in a related semiconductor device has a gate electrode formed embedded, with the interposition of a gate insulating film, in a gate electrode groove formed in a semiconductor substrate, and a first impurity-diffused layer region and a second impurity-diffused region which are formed on the obverse surface side of the semiconductor substrate in such a way as to sandwich the gate electrode groove. A channel is formed along both side surfaces and the bottom surface of the gate in this transistor (see patent literature article 1, for example).

Further, in another related semiconductor device, in a configuration similar to the embedded-gate transistor discussed hereinabove a second impurity-diffused layer is formed to a deep location in such a way as to cover the bottom surface of the gate. (See patent literature article 2, for example).

Meanwhile, MOS (Metal Oxide Insulator) transistors employing an SOI (Silicon On Insulator) substrate have been developed as planar transistors. Such SOI-MOS transistors are characterized in that they have many excellent properties, for example in that the body which forms the channel can be fully depleted, the OFF leakage current is lower than in an MOS transistor formed in a bulk substrate, the S (sub-threshold) coefficient is low, and the current driving force is high.

### Patent Literature

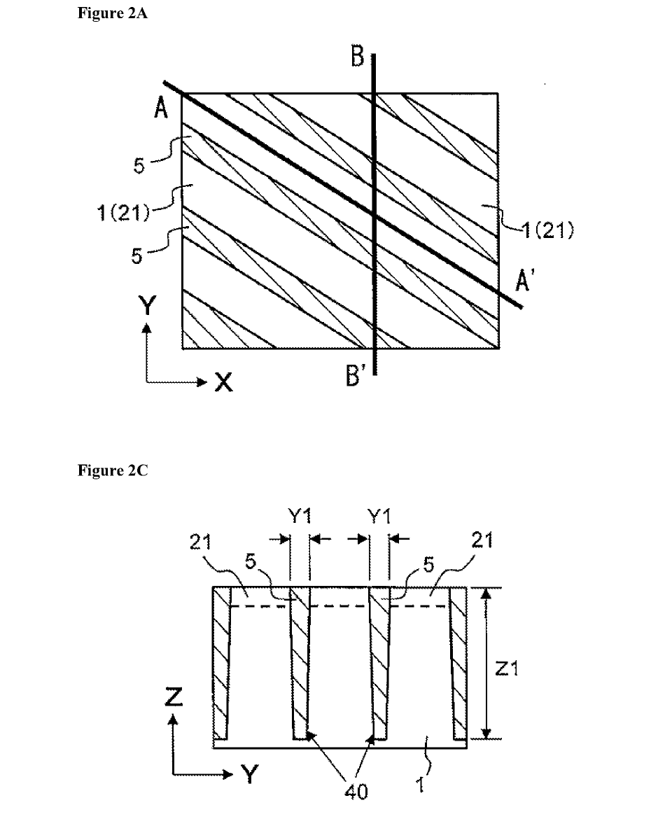

Patent literature article 1: Japanese Patent Kokai 2012-99775 (in particular FIG. 2) or US2012/0112258A1

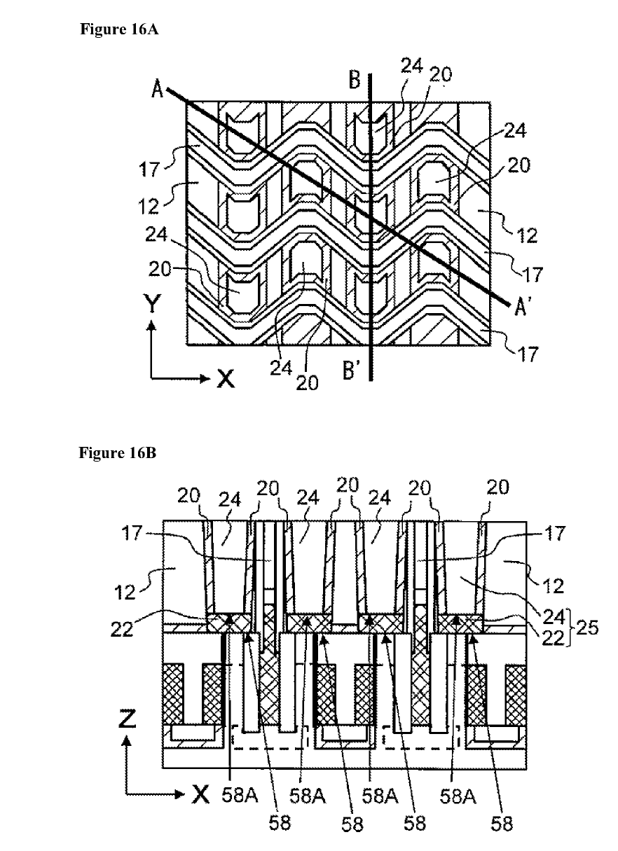

Patent literature article 2: Japanese Patent Kokai 2012-134439 (in particular FIG. 16) or US2012/0132971A1

### SUMMARY OF THE INVENTION

### Problems to be Resolved by the Invention

The semiconductor device having the construction described in patent literature article 1 has the problem that, because a region of the semiconductor substrate located in a lower portion of the transistor is used as the channel, it is difficult to achieve an improvement in the characteristics by fully depleting the channel region.

Further, the semiconductor device having the construction described in patent literature article 2 has the problem that, if a pair of transistors (cell transistors) is configured sharing a second impurity-diffused layer, there is a risk that leakage defects may occur between adjacent cells.

### Means of Overcoming the Problems

A semiconductor device according to one mode of embodiment of the present invention is characterized in that it comprises: a silicon pillar provided by excavating a main surface of a semiconductor substrate; a first diffusion layer provided in an upper portion of the silicon pillar; a second diffusion layer provided extending from a bottom portion of the silicon pillar to one region of the semiconductor substrate that is a continuation of said bottom portion; a gate electrode in contact with at least a first side surface of the silicon pillar, with the interposition of a gate insulating film; a first embedded insulating film surrounding the gate electrode; a second embedded insulating film in contact with a second side surface, which faces the first side surface, of the silicon pillar; and a conductive layer which is electrically connected to the second diffusion layer and is in contact with the second embedded insulating film in a location that is remote from the silicon pillar.

A semiconductor device according to another mode of embodiment of the present invention is characterized in that it comprises: a pair of silicon pillars provided by excavating a main surface of a semiconductor substrate; a pair of first diffusion layers provided respectively in upper portions of the pair of silicon pillars; a second diffusion layer provided extending from bottom portions of the pair of silicon pillars to one region of the semiconductor substrate that is a continuation of said bottom portions; a pair of gate electrodes provided on both sides of the pair of silicon pillars, each in contact with at least a first side surface of each of the pair of silicon pillars, with the interposition of gate insulating films; a conductive layer which is provided between the pair of silicon pillars and is electrically connected to the second diffusion layer; and a pair of first insulating layers which are provided respectively between each of the pair of silicon pillars and the conductive layer, and which are respectively in contact with a side surface of the conductive layer and with second side surfaces, which face the first side surfaces, of the pair of silicon pillars.

A semiconductor device according to yet another mode of embodiment of the present invention is characterized in that it comprises: a pair of silicon pillars provided by excavating a main surface of a semiconductor substrate; a pair of first diffusion layers provided respectively in upper portions of the pair of silicon pillars; a pair of second diffusion layers, each provided extending from a bottom portion of each of the pair of silicon pillars to one region of the semiconductor substrate that is a continuation of said bottom portion; a pair of gate electrodes which are provided between the pair of silicon pillars in such a way as to face one another, and which are each in contact with at least a first side surface of each of the pair of silicon pillars, with the interposition of gate insulating films; and a pair of conductive layers which are respectively in contact with second side surfaces, which face the first side surfaces, of the pair of silicon pillars, with the interposition of first insulating layers, and which are respectively electrically connected to the pair of second diffusion layers.

A method of manufacturing a semiconductor device according to yet another mode of embodiment of the present invention is characterized in that it comprises: a step of forming an element isolation region and an active region by forming an element isolation groove extending in a first direction in a semiconductor substrate, and embedding a first insulating film in said element isolation groove; a step of forming a first diffusion layer in the active region; a step of forming in the semiconductor substrate a first gate groove having a first width in a second direction which intersects the first direction, and, adjacent to the first groove, a second gate groove and a third gate groove having a second width which is narrower than the width of the first groove, and of forming a first silicon pillar between the first gate groove and the second gate groove, and a second silicon pillar between the second gate groove and the third gate groove; a step of forming a gate electrode on a side surface of the first silicon pillar, with the interposition of a gate insulating film; a step of filling the first gate groove and the second gate groove using an embedded insulating film; a step of removing the second silicon pillar; a step of forming a second diffusion layer in a bottom portion of the first silicon pillar by diffusing an impurity from the part from which the second silicon pillar has been removed; and a step of embedding a conductive film into the part from which the second silicon pillar has been removed.

### Advantages of the Invention

According to the present invention, by forming a first diffusion layer in an upper portion of a silicon pillar formed by excavating a main surface of a semiconductor substrate, forming a second diffusion layer in a bottom portion of said silicon pillar, and forming a gate electrode on a first side surface, with the interposition of a gate insulating film, it is possible for the channel region to be fully depleted, and a high current driving force and a low S-coefficient can be obtained. Further, by forming a conductive layer which is electrically connected to the second diffusion layer, in a location that is remote from the silicon pillar, leakage currents between cells can be reduced.

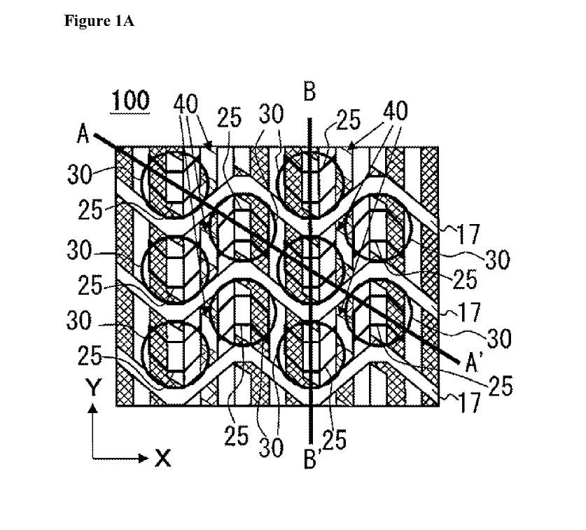

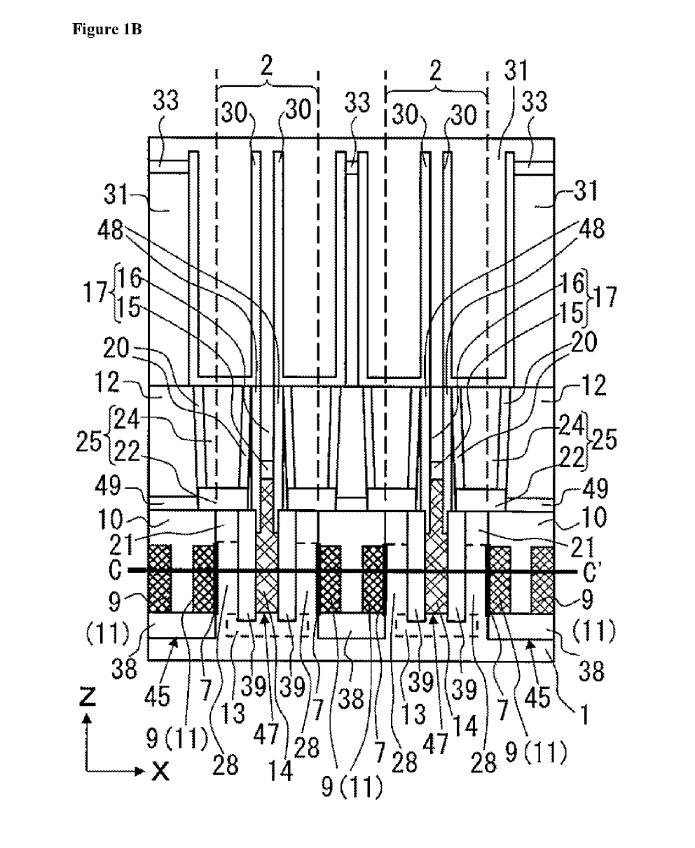

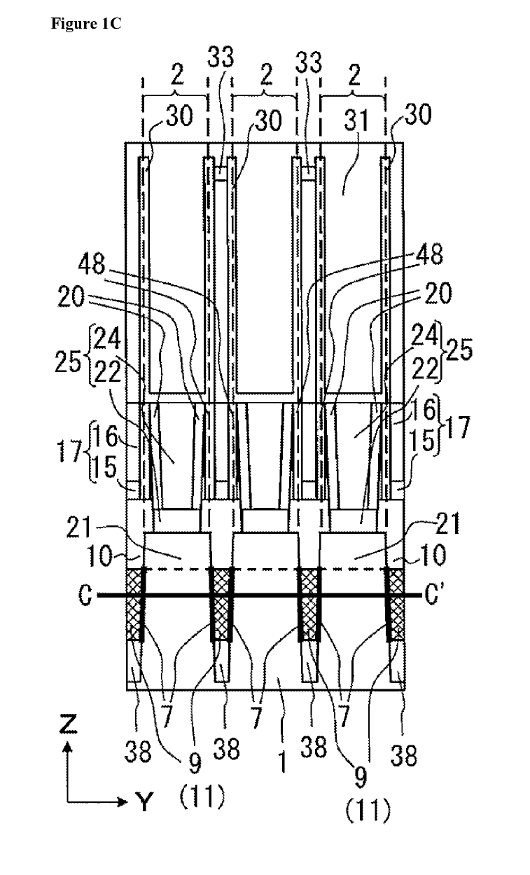

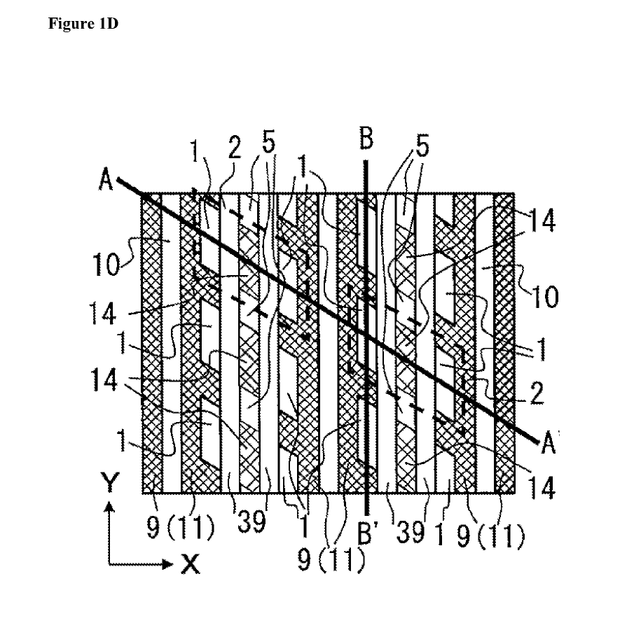

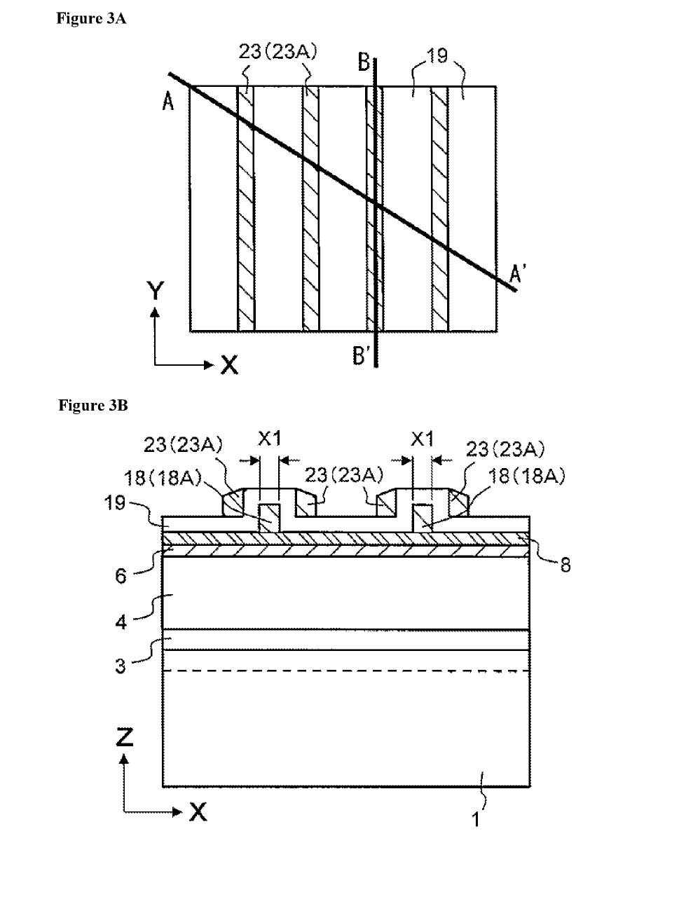

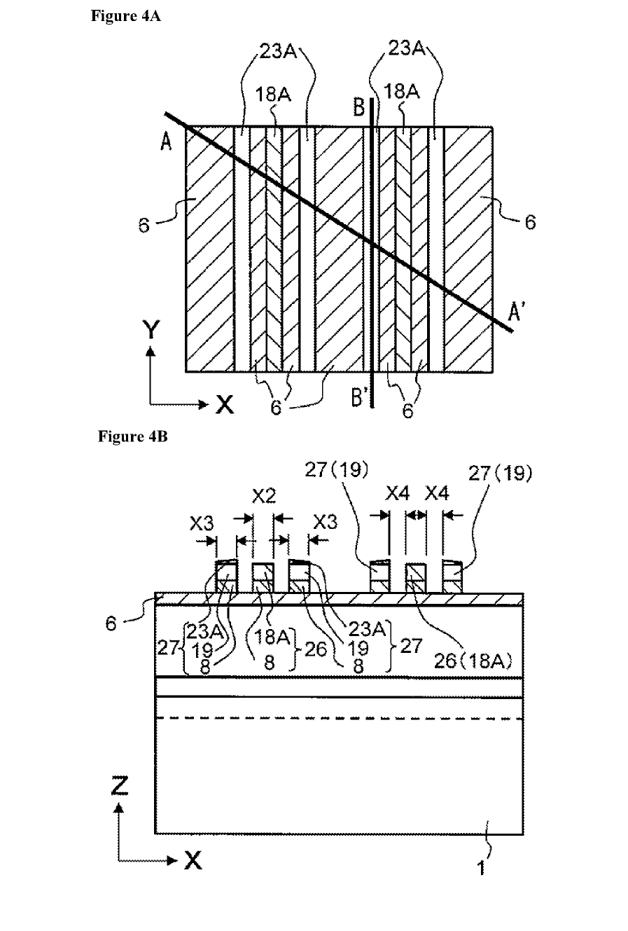

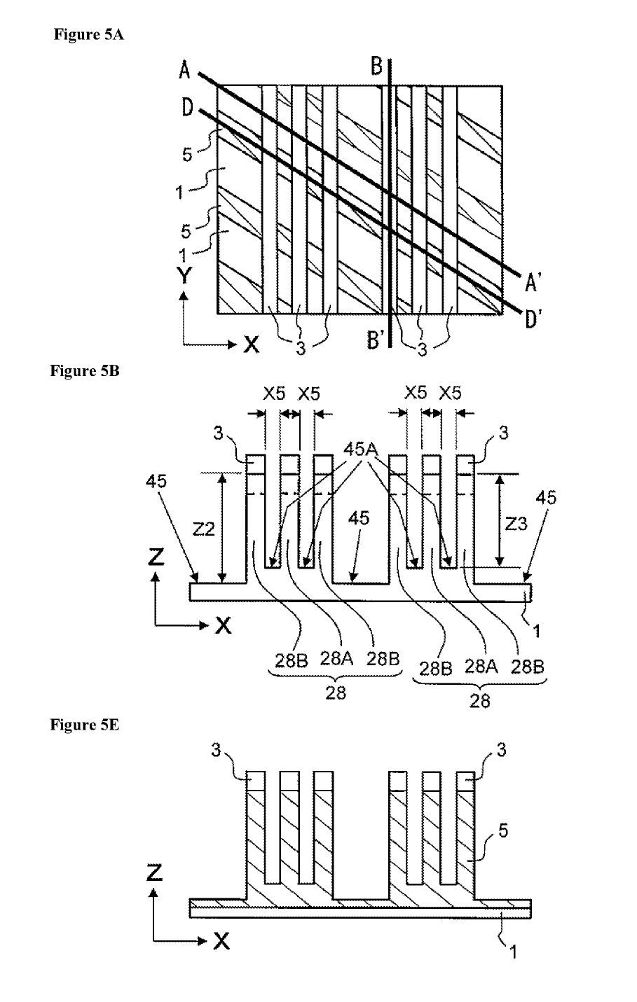

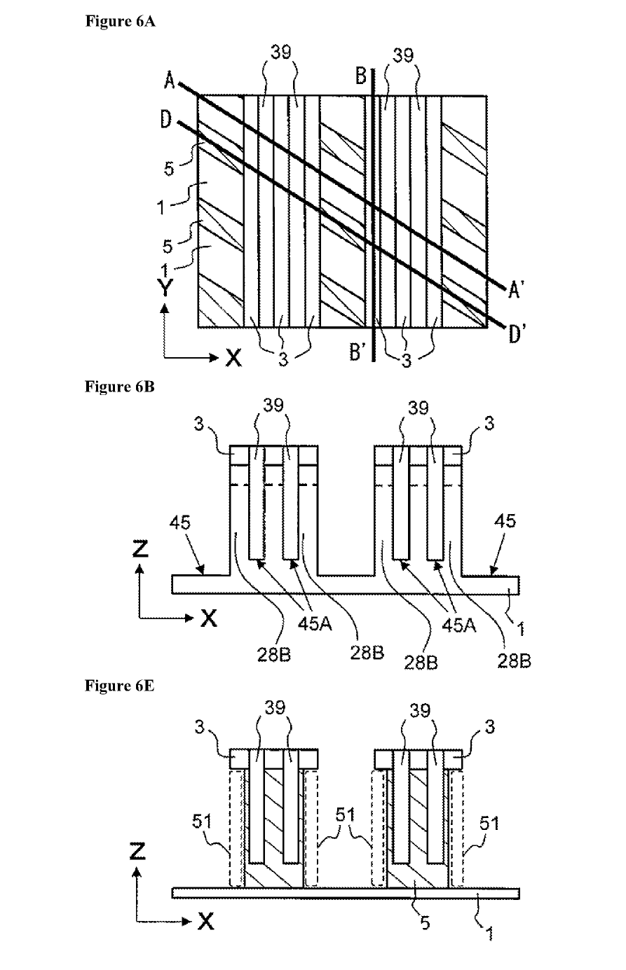

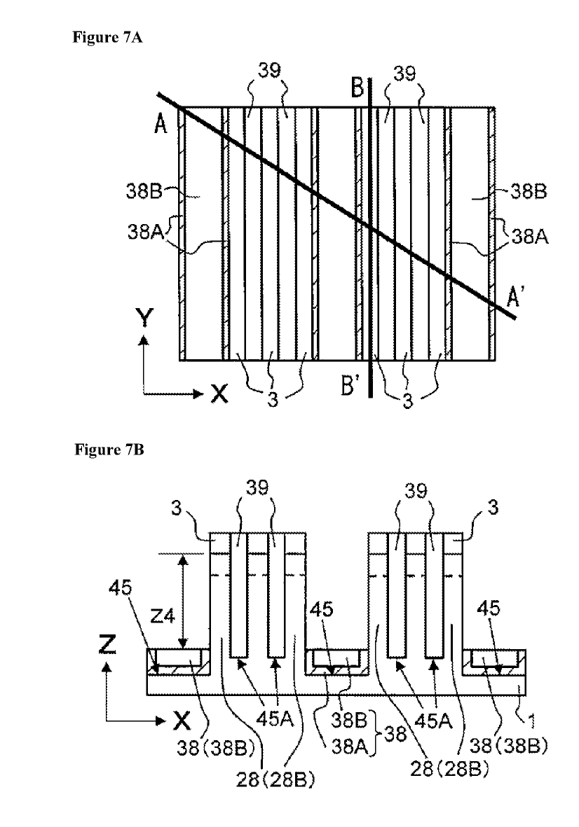

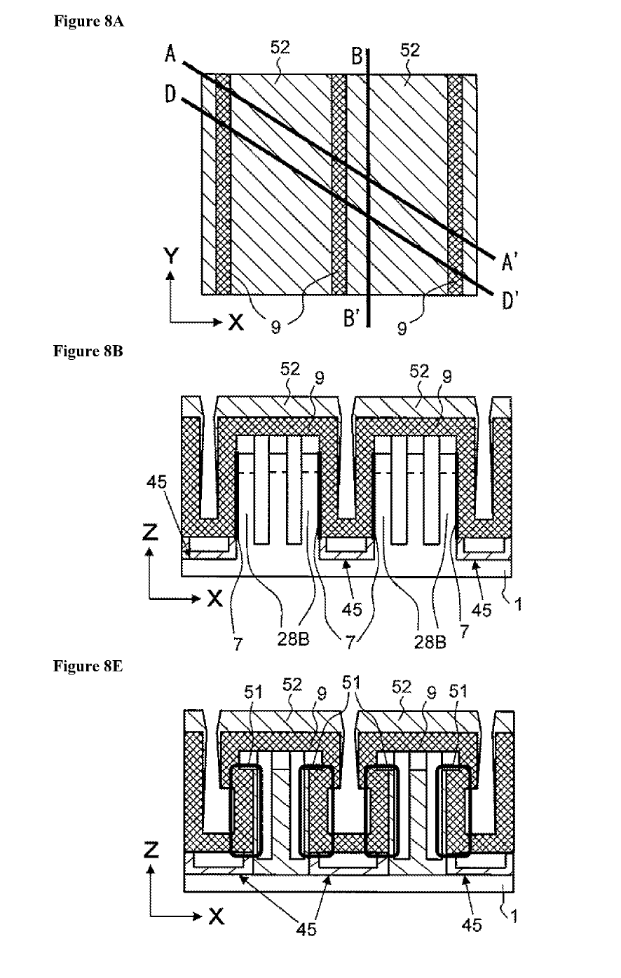

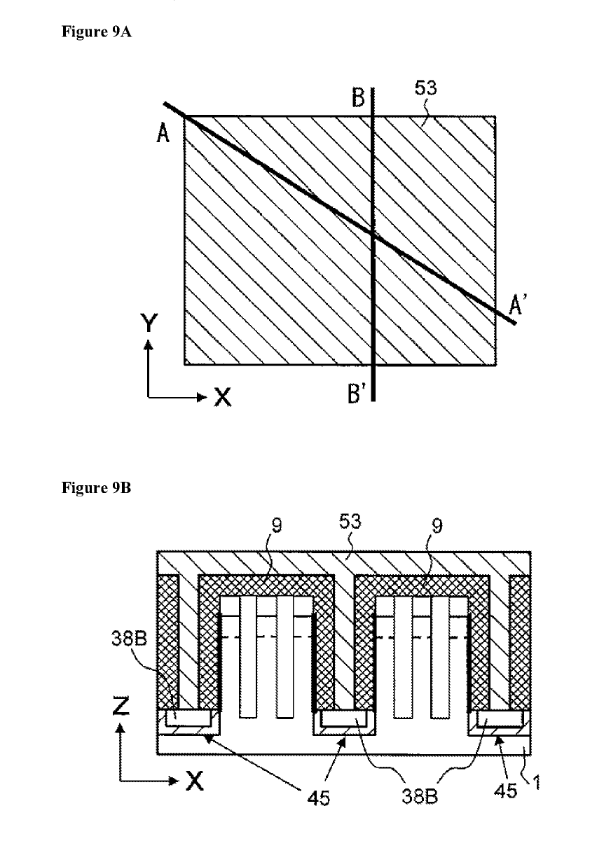

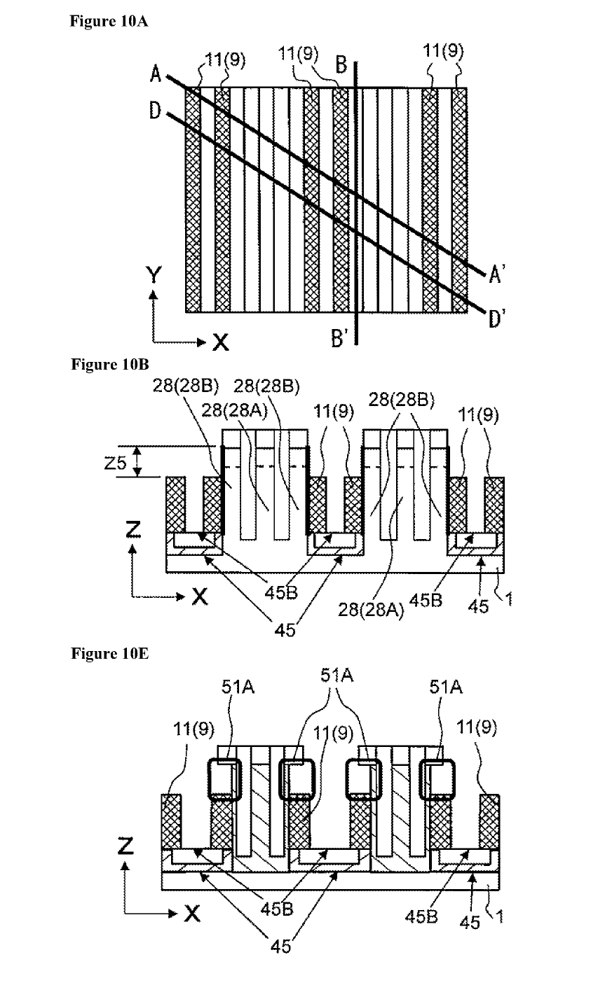

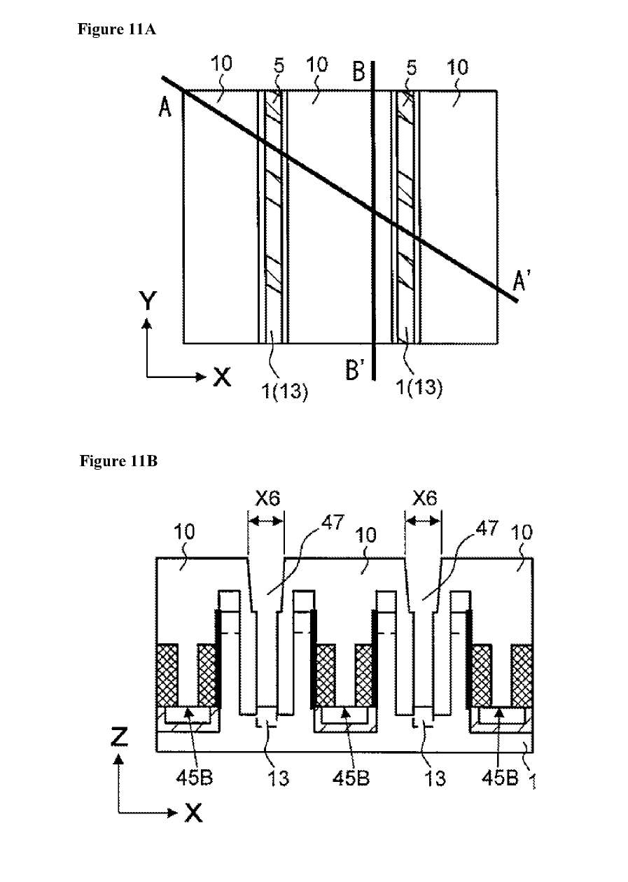

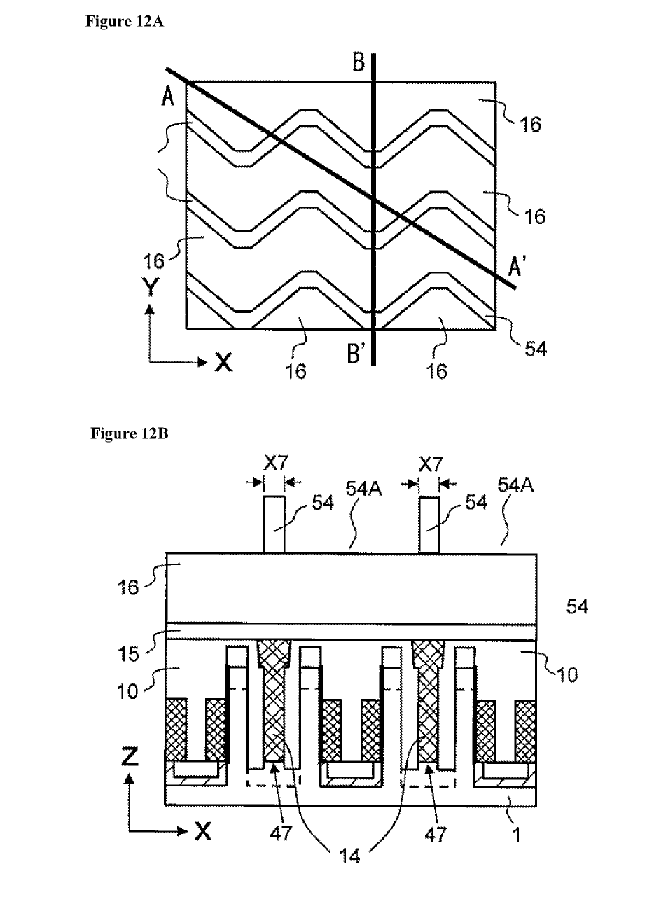

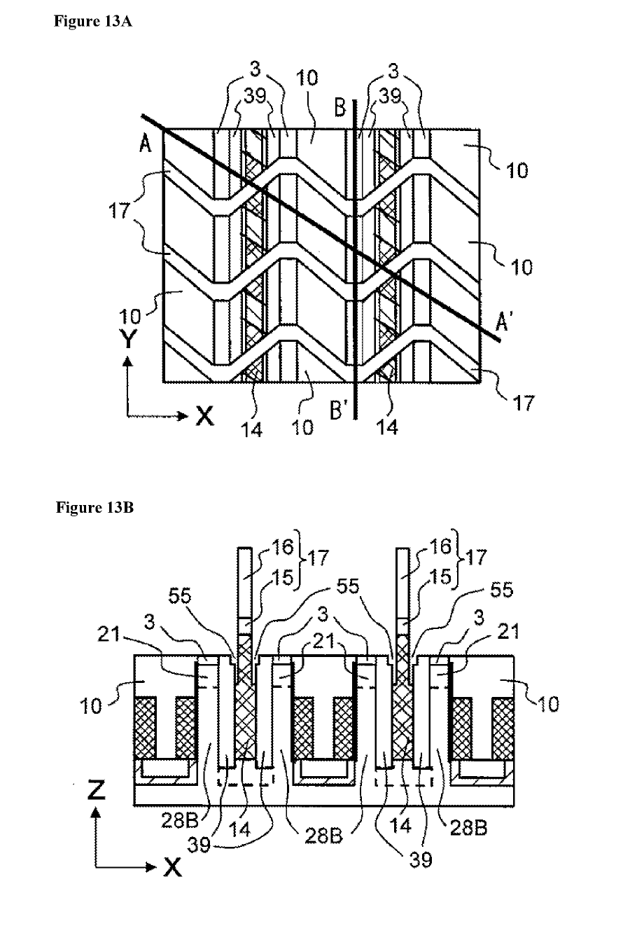

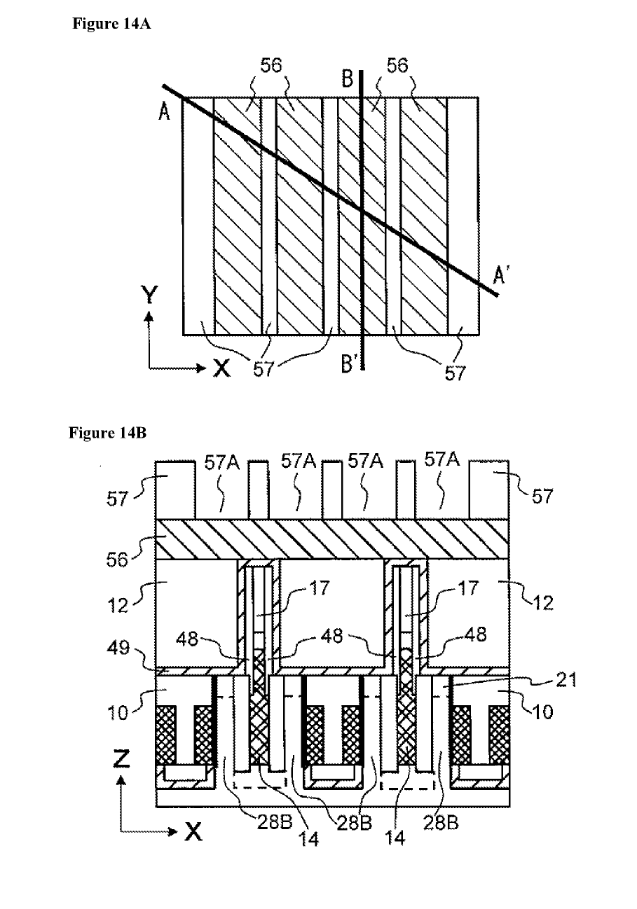

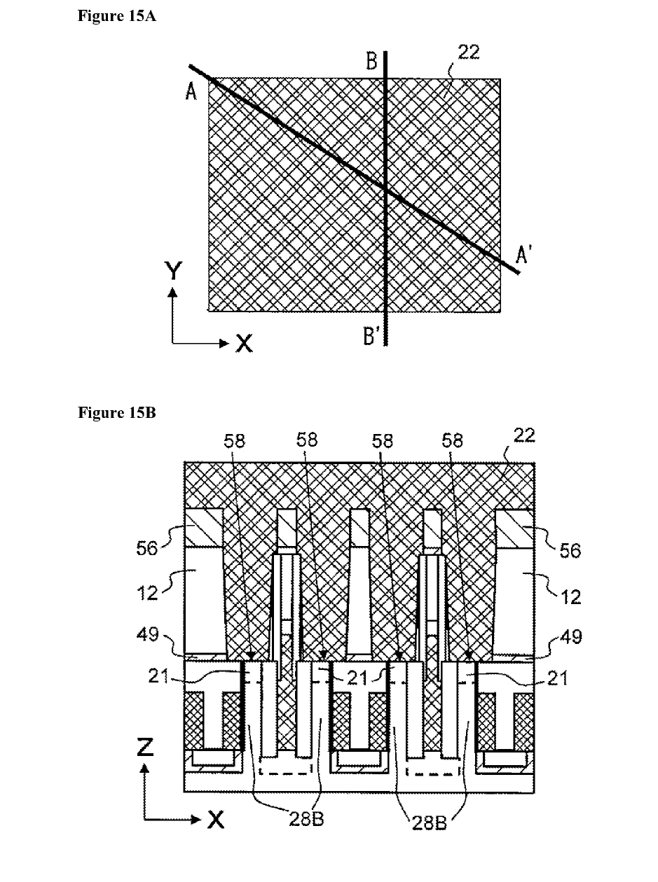

### BRIEF EXPLANATION OF THE DRAWINGS

[FIG. 1A] is a plan view illustrating one configuration example of a semiconductor device according to a first mode of embodiment of the present invention.

[FIG. 1B] is a cross-sectional view through the line A-A′ in FIG. 1A.

[FIG. 1C] is a cross-sectional view through the line B-B′ in FIG. 1A.

[FIG. 1D] is a cross-sectional view through the line C-C′ in FIG. 1B and FIG. 1C.

[FIG. 2A] is a plan view in one step during the manufacture of the semiconductor device in FIGS. 1A to 1D.

[FIG. 2C] is a cross-sectional view through the line B-B′ in FIG. 2A.

[FIG. 3A] is a plan view used to describe the step following the step in FIGS. 2A and 2C.

[FIG. 3B] is a cross-sectional view through the line A-A′ in FIG. 3A.

[FIG. 4A] is a plan view used to describe the step following the step in FIGS. 3A and 3B.

[FIG. 4B] is a cross-sectional view through the line A-A′ in FIG. 4A.

[FIG. 5A] is a plan view used to describe the step following the step in FIGS. 4A and 4B.

[FIG. 5B] is a cross-sectional view through the line A-A′ in FIG. 5A.

[FIG. 5E] is a cross-sectional view through the line D-D′ in FIG. 5A.

[FIG. 6A] is a plan view used to describe the step following the step in FIG. 5A, 5B and 5E.

[FIG. 6B] is a cross-sectional view through the line A-A′ in FIG. 6A.

[FIG. 6E] is a cross-sectional view through the line D-D′ in FIG. 6A.

[FIG. 7A] is a plan view used to describe the step following the step in FIGS. 6A, 6B and 6E.

[FIG. 7B] is a cross-sectional view through the line A-A′ in FIG. 7A.

[FIG. 8A] is a plan view used to describe the step following the step in FIGS. 7A and 7B.

[FIG. 8B] is a cross-sectional view through the line A-A′ in FIG. 8A.

[FIG. 8E] is a cross-sectional view through the line D-D′ in FIG. 8A.

[FIG. 9A] is a plan view used to describe the step following the step in FIGS. 8A, 8B and 8E.

[FIG. 9B] is a cross-sectional view through the line A-A′ in FIG. 9A.

[FIG. 10A] is a plan view used to describe the step following the step in FIGS. 9A and 9B.

[FIG. 10B] is a cross-sectional view through the line A-A′ in FIG. 10A.

[FIG. 10E] is a cross-sectional view through the line D-D′ in FIG. 10A.

[FIG. 11A] is a plan view used to describe the step following the step in FIGS. 10A, 10B and 10E.

[FIG. 11B] is a cross-sectional view through the line A-A′ in FIG. 11A.

[FIG. 12A] is a plan view used to describe the step following the step in FIGS. 11A and 11B.

[FIG. 12B] is a cross-sectional view through the line A-A′ in FIG. 12A.

[FIG. 13A] is a plan view used to describe the step following the step in FIGS. 12A and 12B.

[FIG. 13B] is a cross-sectional view through the line A-A′ in FIG. 13A.

[FIG. 14A] is a plan view used to describe the step following the step in FIGS. 13A and 13B.

[FIG. 14B] is a cross-sectional view through the line A-A′ in FIG. 14A.

[FIG. 15A] is a plan view used to describe the step following the step in FIGS. 14A and 14B.

[FIG. 15B] is a cross-sectional view through the line A-A′ in FIG. 15A.

[FIG. 16A] is a plan view used to describe the step following the step in FIGS. 15A and 15B.

[FIG. 16B] is a cross-sectional view through the line A-A′ in FIG. 16A.

### MODES OF EMBODYING THE INVENTION

Modes of embodying the present invention will now be described in detail with reference to the drawings. Here, a DRAM (Dynamic Random Access Memory) is illustrated as one example of a semiconductor device.

FIG. 1A is a plan view illustrating one configuration example of a portion, more specifically a portion of a memory cell portion, of a DRAM 100 according to a first mode of embodiment of the present invention. It should be noted that in FIG. 1A, in order to facilitate understanding of the arrangement conditions of the constituent elements, the outer peripheries of capacitors located on capacitor contact plugs are illustrated using solid lines.

FIG. 1B and FIG. 1C respectively illustrate a cross-section through the line A-A′ and a cross-section through the line B-B′ in FIG. 1. Further, FIG. 1D illustrates a cross-section through the line C-C′ in FIG. 1B and FIG. 1C. It should be noted that the left-right direction in FIG. 1B is, strictly speaking, a direction that is inclined with respect to the X-direction, but it is described as the X-direction.

The DRAM 100 in this mode of embodiment has a silicon substrate 1 serving as a semiconductor substrate which forms a base. In the following description, the generic term wafer is sometimes used to refer not only to the semiconductor substrate on its own, but also in a condition in which a semiconductor device is being manufactured on the semiconductor substrate, and in a condition in which a semiconductor device has been formed on the semiconductor substrate.

A plurality of active regions 2, isolated from one another by STIs (Shallow Trench Isolations) 5 which are element isolation regions, are defined in the silicon substrate 1. The STIs 5 are formed by disposing insulating films in element isolation grooves 40 formed in the silicon substrate 1. The insulating films used in the STIs 5 may be single-layer films or laminated films.

A pair of embedded MOS (Metal Oxide Semiconductor) transistors is provided in each active region 2. FIG. 1B illustrates four embedded MOS transistors formed in two active regions 2. Several thousands to several hundreds of thousands of embedded MOS transistors are disposed in a cell array portion of an actual DRAM. It should be noted that two MOS transistors that are adjacent to one another and are formed respectively in two adjacent active regions 2 can also be viewed as transistors forming a pair.

Each embedded MOS transistor has a configuration comprising a gate insulating film 7 covering a portion of an inner wall of a word line groove 45 provided at an end, in the X-direction, of the active region 2; a conductive film 9, forming a gate electrode, that covers a side surface portion of the gate insulating film 7; and an impurity-diffused layer 13 (second diffusion layer) which forms one of a source and a drain, in the active region 2 in the vicinity of the lower end of the conductive film 9, and an impurity-diffused layer 21 (first diffusion layer) which forms the other of the source and the drain, in the vicinity of the upper end of the conductive film 9.

The inner wall of the word line groove 45 covered by the gate insulating film 7 is a sidewall of a silicon pillar (referred to hereinafter as the silicon pillar 28) which protrudes upright from the silicon substrate 1. The silicon pillar 28 is formed by excavating the main surface of the silicon substrate 1. The cross-sectional shape (planar shape) of the silicon pillar 28 is rectangular, and the silicon pillar 28 has four side surfaces. One of the four side surfaces (a first side surface) is an inner wall of the word line groove 45. The sidewall of the silicon pillar 28 constituting the inner wall of the word line groove 45 forms the channel region of the embedded MOS transistor.

The conductive film 9 and the gate insulating film 7 are provided not only on one side surface (the first side surface), in the X-direction, of the silicon pillar 28, but also on the two side surfaces in the Y-direction (third and fourth side surfaces). In other words, from among the four side surfaces of the silicon pillar 28, three side surfaces (excluding a second side surface which faces the first side surface) are covered by the conductive film 9 (the cross-sectional shape of the conductive film 9 is a U-shape at the periphery of the silicon pillar 28). The conductive film 9 is sometimes referred to hereinafter as an embedded word line 11.

The gate electrodes formed from portions of the conductive films 9 are disposed on both sides of the pair of silicon pillars disposed in each active region 2. Further, supposing that two MOS transistors that are formed respectively in two adjacent active regions 2 and are adjacent to one another form a pair, it can also be said that the gate electrodes are disposed facing one another between the pair of silicon pillars.

The upper surface and the side surfaces of each conductive film 9 are covered by an embedded insulating film 10 (first embedded insulating film), insulating them from the adjacent conductive film 9, and the bottom surface is covered by an embedded insulating film 38 (third embedded insulating film), insulating it from the silicon substrate 1.

The impurity-diffused layers 13 form impurity-diffused layers common to the two adjacent embedded MOS transistors disposed in each active region 2. In other words, the impurity-diffused layers 13 are provided extending from the bottom portions of the pair of silicon pillars disposed in each active region to one region of the silicon substrate 1. The impurity-diffused layers 13 are sandwiched between embedded insulating films 38 that are adjacent to one another in the X-direction. The impurity-diffused layers 13 are connected to conductive layers 14 which are embedded in bit contact grooves 47 provided above the impurity-diffused layers 13.

Further, supposing that two MOS transistors that are formed respectively in two adjacent active regions 2 and are adjacent to one another form a pair, it can also be said that each of the pair of impurity-diffused layers 13 is provided extending from the bottom portions of the corresponding pillars to one region of the silicon substrate. In this case it can be said that the embedded insulating film 38 is disposed between two impurity-diffused regions 12.

The bit contact grooves 47 into which the conductive layers 14 are embedded are provided in locations that overlap the central portions, in the X-direction, of the active regions 2. Embedded insulating films 39 (second embedded insulating films or first insulating films) are disposed on the side surface portions, in the X-direction, of the bit contact grooves 47.

Each conductive layer 14 is disposed between two embedded MOS transistors disposed in the X-direction in one active region 2. The upper surfaces of the conductive layers 14 are connected to conductive films 15. The upper surfaces of the conductive films 15 are covered by masking films 16. The conductive films 15 and the masking films 16 are sometimes referred to hereinafter collectively as bit lines 17.

In the embedded MOS transistor according to this mode of embodiment, the silicon pillars 28 which form the channel regions are disposed between the conductive films 9 (embedded word lines 11) which form the gate electrodes, and the conductive layers 14 which form bit contact plugs. The silicon pillars 28 and the conductive layers 14 are insulated from one another by means of the embedded insulating films 39. The parts of the conductive layers 14 that are embedded in the bit contact grooves 47 function as bit contact plugs, and the parts located above the bit contact grooves 47 function, in conjunction with the conductive films 15 provided on the upper surfaces of the conductive layers 14, as bit lines.

The impurity-diffused layers 21 disposed above the channel regions in the embedded MOS transistors are connected to capacitors 30 by way of capacitor contact plugs 25 provided on the upper surfaces of the impurity-diffused layers 21.

The capacitor contact plugs 25 have a laminated construction comprising a conductive film 22 and a conductive film 24, and side face portions of the conductive films 24 are covered by side-wall insulating films 20.

The bit lines 17 and the capacitor contact plugs 25 are embedded by means of side-wall insulating films 48, a liner film 49 and a first interlayer insulating film 12. The upper surface of the first interlayer insulating film 12 is covered by the capacitors 30 and an embedding film 31.

The capacitors 30 are crown-type capacitors, formed from a lower electrode, a capacitative insulating film and an upper electrode, which are not shown in the drawings. All the capacitors 30 are embedded by means of the embedding film 31, which is a conductor, and a plate electrode (which is not shown in the drawings) is disposed on the upper surface of the embedding film 31. A support film 33 is connected to a portion of the side surface portion of each capacitor 30 in such a way that adjacent capacitors 30 prevent one another from collapsing.

The plate electrode disposed on the upper surface of the embedding film 31 is covered by a second interlayer insulating film, which is not shown in the drawings, and is connected by way of a contact plug provided in the second interlayer insulating film to an upper metal wiring line provided on the upper surface of the second interlayer insulating film.

The DRAM 100 according to this mode of embodiment is configured as described hereinabove.

According to this mode of embodiment, the DRAM 100 is provided with the embedded word lines 11 on one side surface portion, in the X-direction, of the silicon pillars 28 which form the channel regions, and the embedded word lines 11 are electrically insulated from the silicon substrate 1 by means of the embedded insulating films 38. With such a configuration, the embedded transistor can be formed as a fully-depleted transistor by making the thickness of the silicon pillar 28 (the size of the cross-section cut through a plane parallel to the main surface of the silicon substrate 1) a thickness whereby full depletion is possible. In this way, the ON current of the embedded transistor can be improved compared to a transistor having the structure illustrated in FIG. 2 of patent literature article 1. Further, the S-coefficient of the embedded transistor can be improved by surrounding three side surfaces of the silicon pillar by the embedded word line.

Further, according to this mode of embodiment, the DRAM 100 is provided with the silicon pillars 28 which form the channel regions, between the embedded word lines 11 and the conductive layers 14 which form the bit contact plugs, and the conductive layers 14 and the silicon pillars 28 are electrically insulated from one another by means of the embedded insulating films 39. Thus in this mode of embodiment the conductive layers 14 are disposed remote from the channel regions, with the interposition of the insulating films 39, and therefore the rate of occurrence of leakage defects between adjacent cells can be reduced compared to transistors having the structure illustrated in FIG. 16 of patent literature article 2. With transistors having the structure illustrated in FIG. 16 of patent literature article 2, there is a risk that leakage defects will occur between adjacent cells, as a result of electrons induced in one transistor being implanted into the diffusion layer of an adjacent transistor when the transistor operation is off.

A method of manufacturing the semiconductor device in this mode of embodiment will now be described in detail with reference to FIGS. 2A to 16B.

FIG. 2A to FIG. 16B are process drawings used to described a method of manufacturing for a case in which the semiconductor device is the DRAM 100. Drawings having a drawing number with the suffix ‘A’ (Figure A) are plan views of the DRAM 100 in each manufacturing step. Drawings having a drawing number with the suffix ‘B’ (FIG. B) are cross-sectional views through the line A-A′ in the corresponding Figure A. Drawings having a drawing number with the suffix ‘C’ (Figure C) are cross-sectional views through the line B-B′ in the corresponding Figure A. Drawings having a drawing number with the suffix ‘E’ (Figure E) are cross-sectional views through the line D-D′ in the corresponding Figure A. It should be noted that the following description mainly uses Figure A and Figure B, or Figure A and Figure C, but Figure E is added where necessary.

First a silicon substrate 1 is prepared, and the upper surface thereof is oxidized by thermal oxidation to form a sacrificial film (which is not shown in the drawings), which is a silicon dioxide film.

Next, as illustrated in FIGS. 2A and 2C, an impurity such as phosphorus (P) is implanted from the upper surface of the silicon substrate 1 by ion implantation to form impurity-diffused layers 21 in upper portions of the silicon substrate 1.

Element isolation grooves 40 are then formed in the silicon substrate 1. The element isolation grooves 40 are formed as follows.

First a masking film (which is not shown in the drawings), which is a silicon nitride film (SiN), is laminated to a thickness of 50 nm, for example, by CVD (Chemical Vapor Deposition). The masking film and the sacrificial film are then patterned using photolithography and dry etching to form opening portions (which are not shown in the drawings), portions of the silicon substrate 1 being exposed at the bottom surfaces of the opening portions. Here, the opening portions are disposed in the shape of lines having a width Y1, extending substantially in the X-direction (a direction parallel to the A-A′ cross-section), in a repeating manner with a prescribed spacing in the Y-direction. Further, the width Y1 of the opening portions is, for example, 20 nm.

Dry etching is then used to form element isolation grooves 40 having a depth Z1 of 250 nm, for example, in the silicon substrate 1 that is exposed in the opening portions.

A silicon dioxide film is then deposited over the entire surface of the silicon substrate 1 by CVD in such a way as to fill the interiors of the element isolation grooves 40. Unnecessary silicon dioxide film on the upper surface of the silicon substrate 1 is then removed by CMP (Chemical Mechanical Polishing), leaving the silicon dioxide film (first insulating film) in the element isolation grooves 40. In this way, STIs 5 which form element isolation regions are formed. It should be noted that the width, in the Y-direction, of the STIs 5 is equal to the width Y1 of the opening portions formed in the masking film.

The remaining masking film is then removed by wet etching. At this time, the location of the upper surfaces of the STIs 5 coincides with the upper surface of the silicon substrate 1.

The upper surface of the silicon substrate 1 is then oxidized by thermal oxidation to form an insulating film (which is not shown in the drawings), which is a silicon dioxide film. A first masking film 3, which is a silicon nitride film, is then laminated onto the wafer by CVD, as illustrated in FIGS. 3A and 3B. A second masking film 4, which is an amorphous carbon film (Amorphous Carbon: referred to hereinafter as AC), a third masking film 6, which is a silicon nitride film, a fourth masking film 8, which is amorphous silicon (Amorphous Silicon: hereinafter referred as an AS film) and a fifth masking film 18, which is a silicon dioxide film, are then successively laminated by CVD.

Photolithography is then used to pattern the fifth masking film 18. In this way the fifth masking film 18 forms a line-and-space pattern (rectangular pattern 18A) which extends in the Y-direction and is disposed in a repeating manner with a prescribed spacing in substantially the X-direction (the direction along the line A-A′). The width X1, in the X-direction, of the rectangular pattern 18A is 15 nm, for example.

A sixth masking film 19, which is a silicon nitride film having a thickness of 15 nm, for example, is then deposited by CVD in such a way as to cover the rectangular patterns 18A. The presence of the rectangular patterns 18A causes portions of the sixth masking film 19 to form protruding shapes (referred to hereinafter as protruding portions) which extend in the Y-direction.

A seventh masking film 23, which is a silicon dioxide film having a thickness of 15 nm, for example, is then deposited by CVD in such a way as to cover the sixth masking film 19. The seventh masking film 23 is then etched back by dry etching until the upper surface of the sixth masking film 19 is exposed. In this way, rectangular patterns 23A, which are portions of the seventh masking film 23, remain on the side surfaces, in the X-direction, of the protruding portions of the sixth masking film 19, extending in the Y-direction.

Next, as illustrated in FIGS. 4A and 4B, the exposed sixth masking film 19 and the fourth masking film 8 underlying the exposed sixth masking film 19 are removed by dry etching. In this way, eighth masking films 26, which are laminated films comprising the rectangular patterns 18A and the fourth masking film 8 which is covered by the rectangular patterns 18A, remain on the upper surface of the third masking film 6, extending in the Y-direction. Further, ninth masking films 27, which are laminated films comprising the rectangular patterns 23A, the sixth masking films 19 which are covered by the rectangular patterns 23A, and the underlying fourth masking films 8 remain, extending in the Y-direction. It should be noted that the width X2 of the eighth masking films 26, the width X3 of the ninth masking films 27, and the spacing X4 between the eighth masking films 26 and the ninth masking films 27 are all 15 nm, in accordance with the abovementioned numerical examples. This is because, in the abovementioned numerical examples, the width X1 of the rectangular patterns 18A is 15 nm, and the thicknesses of the sixth masking film 19 and the seventh masking film 23 are each 15 nm.

Next, rectangular patterns (which are not shown in the drawings) extending in the Y-direction are formed in the third masking film 6 and the second masking film 4 by dry etching, using the fourth masking films 8, which are the lowermost layers in the eighth masking films 26 and the ninth masking films 27, as an etching mask. Then, as illustrated in FIGS. 5A and 5B, word line grooves 45 and 45A extending in the Y-direction are formed in the first masking film 3 and the silicon substrate 1 by dry etching, using the second masking films 4, which are the lowermost layers in the rectangular patterns that have been formed, as an etching mask. It should be noted that the word line grooves 45 are grooves (first word line grooves, portions thereof later become first gate grooves) formed between two adjacent ninth masking films 27 (see FIG. 4B), and the word line grooves 45A are grooves (second word line grooves, second and third gate grooves) formed between adjacent eighth masking films 26 and ninth masking films 27 (see FIG. 4B).

The depth Z2 of the word line grooves 45 is 200 nm, for example. The depth Z3 of the word line grooves 45A is less than the depth Z2 of the word line grooves 45. This is because the width X5 of the gaps between adjacent eighth masking films 26 and ninth masking films 27 is narrow, being 15 nm, and therefore the flow of etching gas is poor.

As illustrated in FIG. 5E, the word line grooves 45 and 45A are also formed with the same shape in the STIs 5. Therefore, as can be understood from FIG. 5A, the silicon substrate 1 and the STIs 5 are exposed on the sidewalls of the word line grooves 45. It should be noted that the silicon substrate 1 exposed on the sidewalls of the word line grooves 45 is in the shape of pillars, the periphery of which is surrounded by the word line grooves 45 and the STIs 5. The pillar-shaped parts of the silicon substrate 1 formed below the eighth masking films 26 (see FIG. 4B) are hereinafter referred to as silicon pillars 28A (second silicon pillars), as illustrated in FIG. 5B. Similarly, pillar-shaped parts of the silicon substrate 1 are also formed below the ninth masking films 27 (see FIG. 4B). These parts are referred to as silicon pillars 28B (first silicon pillars). Further, the silicon pillars 28A and 28B are referred to collectively as silicon pillars 28. The width of the word line grooves 45, for example, must be set in such a way that the silicon pillars 28 have a thickness (cross-sectional area in a direction parallel to the main surface of the silicon substrate 1) whereby the silicon pillars 28 can be fully depleted.

An embedded insulating film 39, which is a silicon nitride film having a thickness such that it completely fills the word line grooves 45A, is next formed by CVD, as illustrated in FIGS. 6A and 6B. The thickness of the embedded insulating film 39 is 15 nm, for example, equal to the width X5 of the word line grooves 45A. The word line grooves 45 are not completely filled by the embedded insulating film 39, but the inner surfaces thereof are covered by the embedded insulating film 39.

The embedded insulating film 39 covering the inner surfaces of the word line grooves 45 is then removed by wet etching. In this way, the side surface portions, in the X-direction, of the silicon pillars 28B and the STIs 5 which form the word line grooves 45 are exposed. Meanwhile, the interiors of the word line grooves 45A are filled by the embedded insulating film 39, and the wet etching chemical liquid cannot flow thereinto. The embedded insulating film 39 filling the inner walls of the word line grooves 45A therefore remains as it is. It should be noted that with respect to each silicon pillar 28B, the side surface closer to the word line groove 45 is sometimes referred to as the one side surface in the X-direction, and the side surface closer to the word line groove 45A is sometimes referred to as the other side surface in the X-direction.

Next, as illustrated in FIG. 6E, a portion of the STI5, which is the silicon dioxide film exposed in the word line grooves 45, is removed by wet etching. At this time, the first masking film 3, which is the silicon nitride film adjacent to the word line groove 45, remains to form an overhanging portion. Void portions 51 below the overhanging portions are hereinafter included when referring to the word line grooves 45.

As illustrated in FIGS. 7A and 7B, an embedded insulating film 38A, which is a silicon nitride film having a thickness of 5 nm, for example, is then deposited by CVD in such a way as to cover the inner surfaces of the word line grooves 45. An embedded insulating film 38B, which is a silicon dioxide film, is then deposited by CVD in such a way as to fill the interiors of the word line grooves 45. The embedded insulating films 38A and 38B are hereinafter referred to collectively as an embedded insulating film 38.

Next, the embedded insulating film 38 formed on the upper surfaces of the first masking films 3 and the embedded insulating films 39 is removed by CMP, to cause the location of the upper surface of the embedded insulating film 38 to coincide with the location of the upper surface of the first masking films 3. Next, portions of the embedded insulating films 38B in the word line grooves 45 are removed by wet etching in such a way that the depth Z4 from the upper surfaces of the silicon pillars 28 is 150 nm, for example. The embedded insulating films 38A that have been exposed by removing the embedded insulating films 38B are then removed. At this time, the location of the upper surfaces of the remaining embedded insulating films 38A is made to coincide with the location of the upper surfaces of the embedded insulating films 38B. The location of the upper surfaces of the embedded insulating films 38A (the bottom surfaces of first gate grooves) is therefore a location that is higher than the location of the bottom surfaces of the word line grooves 45A. Here also, portions of the STIs 5 and one side surface, in the X-direction, of the silicon pillars 28B are exposed on the side surfaces of the word line grooves 45.

Next, as illustrated in FIGS. 8A and 8B, the side surfaces of the silicon pillars 28B exposed in the word line grooves 45 are oxidized by lamp annealing to form gate insulating films 7. Next, a conductive film 9, which is titanium nitride (TiN) having a thickness of 15 nm, for example, is deposited by CVD in such a way as to cover the inner surfaces of the word line grooves 45. As illustrated in FIG. 8E, the conductive film 9 is formed in such a way as to completely fill the void portions 51. Next, a masking film 52, which is a silicon dioxide film, is deposited onto the upper surface of the conductive film 9 by plasma CVD. The masking film 52 is deposited by plasma CVD which has poor covering characteristics, and therefore very little of the masking film 52 is deposited on the inner surfaces of the word line grooves 45, and the conductive film 9 is exposed in the interiors of the word line grooves 45.

Next, as illustrated in FIGS. 9A and 9B, the conductive film 9 exposed inside the word line grooves 45 is etched back by dry etching. The conductive film 9 is thus divided at the locations of the upper surfaces of the embedded insulating films 38B. A sacrificial film 53, which is a silicon dioxide film, is then deposited by CVD in such a way as to cover the remaining conductive films 9. At this time, the sacrificial film 53 is formed using CVD which has excellent covering characteristics, and therefore the sacrificial film 53 fills the interiors of the word line grooves 45.

Next, as illustrated in FIGS. 10A and 10B, portions of the sacrificial film 53 (see FIG. 9B) are removed by dry etching in such a way that the depth Z5 from the upper surface of the silicon pillars 28 is 100 nm, for example. The exposed conductive films 9 are then removed by dry etching. At this time, upper portions of the conductive films 9 embedded in the void portions 51 (see FIG. 8E) are also removed, as illustrated in FIG. 10E, to form new void portions 51A. The height of the conductive films 9 remaining in the void portions 51 is the same as the height of the other conductive films 9 remaining in the word line grooves 45. Next, the sacrificial films 53 remaining in the interiors of the word line grooves 45 are removed by dry etching. This completes the embedded word lines 11 formed from the conductive films 9. At this time, new word line grooves 45B are formed between adjacent embedded word lines 11.

As illustrated in FIGS. 11A and 11B, an embedded insulating film 10, which is a silicon nitride film having a thickness of 30 nm, for example, is then deposited by CVD in such a way as to fill the word line grooves 45B and the void portions 51A (see FIG. 10E). Next, portions of the embedded insulating film 10 are removed by photolithography and dry etching in such a way as to expose the upper surfaces of the silicon pillars 28A (see FIG. 10B) and the STIs 5, to form bit contact grooves 47 which extend in the Y-direction and in which the width X6 of the opening portion is 30 nm, for example. Further, the exposed silicon pillars 28A are removed by dry etching. In this way, portions of the upper surfaces of the silicon substrate 1 are exposed in the bit contact grooves 47 together with the STIs 5. Next, arsenic (As) or the like is implanted as an impurity, using ion implantation, into upper portions of the silicon substrate 1 exposed at the bottom portions of the bit contact grooves 47, to form impurity-diffused layers 13.

Next, as illustrated in FIGS. 12A and 12B, a conductive layer 14, which is a polysilicon film doped with phosphorus, is deposited by CVD in such a way as to fill the bit contact grooves 47. The conductive layer 14 formed on the upper surfaces of the embedded insulating films 10 is then etched back by dry etching to leave the conductive layer 14, which functions as a bit contact plug, in the bit contact grooves 47. A conductive film 15, which is a laminated film comprising titanium nitride (TiN) and tungsten (W), is then deposited by sputtering, to a total thickness of 20 nm, for example, on the upper surfaces of the embedded insulating films 10 and the conductive layers 14. A masking film 16, which is a silicon nitride film having a thickness of 150 nm, for example, is then deposited by CVD on the upper surface of the conductive film 15.

A resist film is then formed on the masking film 16. Portions of the resist mask are then removed by photolithography to form opening portions 54A. Portions of the masking film 16 are exposed at the bottom surfaces of the opening portions 54A. In this way photoresist masks 54, the width X7 of which is 20 nm, for example, are formed on the masking film 16. The photoresist masks 54 are formed in such a way as to extend substantially in the X-direction, while meandering in such a way as not to overlap areas in which capacitor contact plugs, discussed hereinafter, are to be disposed. The photoresist masks 54 include parts that pass above the conductive layers 14 and parts that extend along the STIs 5 above the STIs 5.

Next, as illustrated in FIGS. 13A and 13B, portions of the exposed masking film 16 and the conductive film 15 and embedded insulating film 10 underlying the exposed masking film 16 are removed by dry etching, using the photoresist masks 54 as a mask. At this time, because the first masking films 3 have been left on the upper surfaces of the silicon pillars 28B, the impurity-diffused layers 21 are protected.

The remaining conductive films 15 form bit lines 17. Because portions of the masking film 16 also remain on the upper surfaces of the remaining conductive films 15, the remaining conductive films 15 and masking films 16 are hereinafter referred to collectively as the bit lines 17.

Further, in order to prevent short-circuiting between capacitor contact plugs, which are discussed hereinafter, and the conductive layers 14, grooves (pockets) 55 are formed at boundary portions in the vicinity of the upper portions of the embedded insulating films 39 and the conductive layers 14.

Next, as illustrated in FIGS. 14A and 14B, a silicon nitride film having a thickness of 5 nm, for example, is deposited by CVD in such a way as to cover the exposed bit lines 17 and conductive layers 14. The deposited silicon nitride film is then etched back to form side-wall insulating films 48, formed from the silicon nitride film, on side surface portions of the bit lines 17 and the conductive layers 14. At this time, the first masking films 3 (see FIG. 13B) on the upper surfaces of the silicon pillars 28B are removed together with the etched-back silicon nitride film. Further, the grooves (pockets) 55 (see FIG. 13B) are filled by the side-wall insulating films 48. Here, the silicon nitride film is etched back under conditions having a high etching selectivity with respect to the silicon pillars 28B, thereby protecting the impurity-diffused layers 21.

Next, a liner film 49, which is a silicon nitride film having a thickness of 5 nm, for example, is deposited by CVD in such a way as to cover the embedded insulating films 10 and the side-wall insulating films 48. A first interlayer insulating film 12, which is a silicon dioxide film, is then deposited by CVD in such a way as to embed the liner film 49. A masking film 56, which is a silicon dioxide film having a thickness of 50 nm, for example, is then deposited by CVD in such a way as to cover the upper surface of the first interlayer insulating film 12. Further, a photoresist film having a thickness of 30 nm, for example, is formed on the masking film 56. Opening portions 57A are formed in the photoresist film by photolithography, to form photoresist masks 57. The photoresist masks 57 are disposed in such a way as to extend in the Y-direction, above each of the embedded insulating films 10 and the bit lines 17. Portions of the masking film 56 are exposed at the bottom surfaces of the opening portions 57A.

Next, as illustrated in FIGS. 15A and 15B, the exposed masking film 56 and portions of the first interlayer insulating film 12 and the liner film 49 underlying the exposed masking films 56 are removed by dry etching, using the photoresist masks 57 (see FIG. 14B) as an etching mask, to form capacitor contact grooves 58 exposing the upper surfaces of the silicon pillars 28B. When the liner film 49 is removed, etching conditions having a high etching selectivity with respect to the silicon pillars 28B are employed, thereby protecting the impurity-diffused layers 21. Next, a conductive film 22, which is a polysilicon film doped with phosphorus, is deposited by CVD in such a way as to fill the capacitor contact grooves 58.

Next, as illustrated in FIGS. 16A and 16B, the conductive film 22 is etched back by dry etching in such a way that the upper surface of the conductive film 22 is in a location that is lower than the bottom surfaces of the bit lines 17. Portions of the conductive film 22 remain in the bottom portions of the capacitor contact grooves 58. The remaining conductive films 22 cause the capacitor contact grooves 58 to become shallower, thereby forming new capacitor contact grooves 58A.

Next, a silicon nitride film having a thickness of 10 nm, for example, is deposited by CVD in such a way as to cover the inner surfaces of the capacitor contact grooves 58A. The deposited silicon nitride film is then etched back by dry etching to form side-wall insulating films 20 on the side surface portions of the capacitor contact grooves 58A.

Next, a conductive film 24, which is tungsten, is deposited by CVD in such a way as to fill the capacitor contact grooves 58A. The conductive film 24 on the upper surface of the first interlayer insulating film 12 is removed by CMP, leaving the conductive film 24 in the capacitor contact grooves 58A. The remaining conductive films 24 together with the conductive films 22 form capacitor contact plugs 25.

Known methods are subsequently used to form various constituent elements, which are not shown in the drawings, from the capacitors 30 (see FIG. 1B) to the upper metal wiring lines, and to form a protective film, thereby completing the DRAM 100.

Modes of embodiment of the present invention have been described hereinabove, but various variations and modifications may be made within the scope of the present invention, without limitation to the abovementioned modes of embodiment of the present invention. The film materials, film thicknesses, deposition methods, etching methods and the like discussed hereinabove are merely shown by way of example, and other materials and the like may also be employed.

This application is based upon and claims the benefit of priority from Japanese Patent Application No. 2013-1782, filed on Jan. 9, 2013, the entire disclosure of which is incorporated herein by reference.

### EXPLANATION OF THE REFERENCE NUMBERS

1 Silicon substrate

2 Active region

3 First masking film

4 Second masking film

5 STI

6 Third masking film

7 Gate insulating film

8 Fourth masking film

9 Conductive film

10 Embedded insulating film

11 Embedded word line

12 First interlayer insulating film

13 Impurity-diffused layer

14 Conductive layer

15 Conductive film

16 Masking film

17 Bit line

18 Fifth masking film

18A Rectangular pattern

19 Sixth masking film

20 Side-wall insulating film

21 Impurity-diffused layer

22 Conductive film

23 Seventh masking film

23A Rectangular pattern

24 Conductive film

25 Capacitor contact plug

26 Eighth masking film

27 Ninth masking film

28 Silicon pillar

28A Silicon pillar

28B Silicon pillar

30 Capacitor

31 Embedding film

33 Support film

38 Embedded insulating film

38A Embedded insulating film

38B Embedded insulating film

39 Embedded insulating film

40 Element isolation groove

45 Word line groove

45A Word line groove

45B Word line groove

47 Bit contact groove

48 Side-wall insulating film

49 Liner film (backing film)

51 Void portion

51A Void portion

52 Masking film

53 Sacrificial film

54 Photoresist mask

54A Opening portion

55 Groove (pocket)

56 Masking film

57 Photoresist mask

57A Opening portion

58 Capacitor contact groove

58A Capacitor contact groove

100 DRAM

1. A semiconductor device comprising:
a silicon pillar provided by excavating a main surface of a semiconductor substrate;
a first diffusion layer provided in an upper portion of the silicon pillar;
a second diffusion layer provided extending from a bottom portion of the silicon pillar to one region of the semiconductor substrate that is a continuation of said bottom portion;
a gate electrode in contact with at least a first side surface of the silicon pillar, with the interposition of a gate insulating film;
a first embedded insulating film surrounding the gate electrode;
a second embedded insulating film in contact with a second side surface, which faces the first side surface, of the silicon pillar; and
a conductive layer which is electrically connected to the second diffusion layer and is in contact with the second embedded insulating film in a location that is remote from the silicon pillar.

2. The semiconductor device of claim 1, wherein the silicon pillar has third and fourth side surfaces which are a continuation of the first side surface and the second side surface and which face one another, and the gate electrode is in contact with the first, third and fourth side surfaces with the interposition of the gate insulating film.

3. The semiconductor device of claim 1, wherein the silicon pillar has a thickness whereby a part thereof between the first diffusion layer and the second diffusion layer can be fully depleted.

4. The semiconductor device of claim 1, wherein the conductive layer comprises polysilicon doped with phosphorus.

5. The semiconductor device of claim 1, comprising a bit line connected to the conductive layer.

6. The semiconductor device of claim 1, comprising a capacitor connected to the first diffusion layer by way of a capacitor contact plug.

7. The semiconductor device of claim 1, wherein the first embedded insulating film also covers an upper portion of the gate electrode.

8. The semiconductor device of claim 1, comprising a third embedded insulating film in contact with a lower portion of the gate electrode.

9. The semiconductor device of claim 8, wherein the third embedded insulating film is a film having a double-layer structure.

10. The semiconductor device of claim 1, wherein the gate electrode is provided in a first word line groove, and the second embedded insulating film is provided in a second word line groove which is shallower than the first word line groove.

11. The semiconductor device of claim 10, wherein an element isolation region extending in a first direction is formed in the semiconductor substrate, and the first word line groove and the second word line groove extend in a second direction which intersects the first direction.

12. A semiconductor device comprising:
a pair of silicon pillars provided by excavating a main surface of a semiconductor substrate;
a pair of first diffusion layers provided respectively in upper portions of the pair of silicon pillars;
a second diffusion layer provided extending from bottom portions of the pair of silicon pillars to one region of the semiconductor substrate that is a continuation of said bottom portions;
a pair of gate electrodes provided on both sides of the pair of silicon pillars, each in contact with at least a first side surface of each of the pair of silicon pillars, with the interposition of gate insulating films;
a conductive layer which is provided between the pair of silicon pillars and is electrically connected to the second diffusion layer; and
a pair of first insulating layers which are provided respectively between each of the pair of silicon pillars and the conductive layer, and which are respectively in contact with a side surface of the conductive layer and with second side surfaces, which face the first side surfaces, of the pair of silicon pillars.

13. The semiconductor device of claim 12, wherein each of the pair of silicon pillars has third and fourth side surfaces which are a continuation of the first side surface and the second side surface and which face one another, and each of the pair of gate electrodes is in contact with the first, third and fourth side surfaces of the corresponding silicon pillar, with the interposition of the gate insulating film.

14. The semiconductor device of claim 12, wherein each of the pair of silicon pillars has a thickness whereby a part thereof between the first diffusion layer and the second diffusion layer can be fully depleted.

15. The semiconductor device of claim 12, wherein the conductive layer comprises polysilicon doped with phosphorus.

16. The semiconductor device of claim 12, comprising a bit line connected to the conductive layer.

17. The semiconductor device of claim 12, comprising capacitors connected to each of the pair of first diffusion layers by way of capacitor contact plugs.

18. The semiconductor device of claim 12, comprising a first embedded insulating film covering the side surfaces and an upper portion of each of the pair of gate electrodes.

19. The semiconductor device of claim 12, wherein each of the pair of gate electrodes is provided in a first word line groove, and each of the pair of first insulating films is provided in a second word line groove which is shallower than the first word line groove.

20. The semiconductor device of claim 19, wherein an element isolation region extending in a first direction is formed in the semiconductor substrate, and the first word line groove and the second word line groove extend in a second direction which intersects the first direction.

21. A semiconductor device comprising:
a pair of silicon pillars provided by excavating a main surface of a semiconductor substrate;
a pair of first diffusion layers provided respectively in upper portions of the pair of silicon pillars;
a pair of second diffusion layers, each provided extending from a bottom portion of each of the pair of silicon pillars to one region of the semiconductor substrate that is a continuation of said bottom portion;
a pair of gate electrodes which are provided between the pair of silicon pillars in such a way as to face one another, and which are each in contact with at least a first side surface of each of the pair of silicon pillars, with the interposition of gate insulating films; and
a pair of conductive layers which are respectively in contact with second side surfaces, which face the first side surfaces, of the pair of silicon pillars, with the interposition of first insulating layers, and which are respectively electrically connected to the pair of second diffusion layers.

22. The semiconductor device of claim 21, wherein each of the pair of silicon pillars has third and fourth side surfaces which are a continuation of the first side surface and the second side surface and which face one another, and each of the pair of gate electrodes is in contact with the first, third and fourth side surfaces of the corresponding silicon pillar, with the interposition of the gate insulating film.

23. The semiconductor device of claim 21, wherein each of the pair of silicon pillars has a thickness whereby a part thereof between the first diffusion layer and the second diffusion layer is fully depleted.

24. The semiconductor device of claim 21, comprising a first embedded insulating film covering the side surfaces and upper portions of the pair of gate electrodes.

25. The semiconductor device of claim 21, wherein the pair of gate electrodes are provided in first word line grooves, and the first insulating films are provided in second word line grooves which are shallower than the first word line grooves.

26. A method of manufacturing a semiconductor device, comprising:
forming an element isolation region and an active region by forming an element isolation groove extending in a first direction in a semiconductor substrate, and embedding a first insulating film in said element isolation groove;
forming a first diffusion layer in the active region;
forming in the semiconductor substrate a first gate groove having a first width in a second direction which intersects the first direction, and, adjacent to the first groove, a second gate groove and a third gate groove having a second width which is narrower than the width of the first groove, and forming a first silicon pillar between the first gate groove and the second gate groove, and a second silicon pillar between the second gate groove and the third gate groove;
forming a gate electrode on a side surface of the first silicon pillar, with the interposition of a gate insulating film;
filling the first gate groove and the second gate groove using an embedded insulating film;
removing the second silicon pillar;
forming a second diffusion layer in a bottom portion of the first silicon pillar by diffusing an impurity from the part from which the second silicon pillar has been removed; and
embedding a conductive film into the part from which the second silicon pillar has been removed.

27. The method of claim 26, wherein the first gate groove is formed in such a way as to be shallower than the second gate groove and the third gate groove.

28. The method of claim 26, wherein an embedded insulating film is formed in a bottom portion of the first gate groove before forming the gate electrode.

29. The method of claim 26, wherein forming the gate electrode is performed in such a way that three side surfaces of the first silicon pillar are covered.

30. The method of claim 26, wherein forming the first silicon pillar is performed in such a way that the first silicon pillar has a thickness whereby a channel of a transistor formed from the gate electrode, the first diffusion layer and the second diffusion layer is fully depleted.
